(19) United States
(12) Patent Application Publication
(10) Pub. No.: US 2026/0163565 A1
(43) Pub. Date: Jun. 11, 2026

(54) ELECTRIC CIRCUIT COMPRISING BIPOLAR SWITCH

(71) Applicant: STMicroelectronics International N.V., Geneva (CH)

(72) Inventors: Vincent Knopik, Crets en Belledonne (FR); Benoit Butaye, Meylan (FR)

(21) Appl. No.: 19/411,999

(22) Filed: Dec. 8, 2025

(30) Foreign Application Priority Data
Dec. 9, 2024 (EP) 24315560.3
Nov. 27, 2025 (EP) 25315418.1

(51) Int. Cl. H03K 17/16

(52) U.S. Cl. CPC H03K 17/16

(57) ABSTRACT

The present description concerns a switch circuit comprising at least one first bipolar transistor configured to be coupled to at least one electrical component to be switched, the bipolar transistor having a first conduction electrode coupled to a reference electrical potential via at least one resistor or inductor, or a second transistor.

### CROSS-REFERENCE TO RELATED APPLICATIONS

This application claims priority to European Application No. EP24315560.3, filed on Dec. 9, 2024 and to European Application No. EP25315418.1 filed on Nov. 27, 2025, which applications are hereby incorporated herein by their reference.

### TECHNICAL FIELD

The present disclosure generally concerns the field of switch circuits, switches, and multiplexers implementing these switch circuits and switches.

### BACKGROUND

Electrical components of variable value, such as variable resistors, variable capacitors, or variable inductors, can be obtained by using one or more switches to gradually increase or decrease the value of these components according to the on or off state of these switches.

The switches used to create components of variable value have a large size to ensure the lowest possible on-state resistance and also have a parasitic capacitance which impacts the frequency response of the component of variable value.

At the same time, the decrease in chip surface areas dedicated to radio frequency signals implies being able to select or change the load, the inductance values of the transformers, or even the inputs/outputs. It is thus important to be able to have multiplexers available to perform these selections.

### SUMMARY

There exists a need to provide a solution enabling to obtain switches for a component of variable value that can be smaller in size and enable to decrease the impact of their parasitic capacitance.

There further exists a need to have multiplexers that can operate with low losses, on small chip surface areas and at low cost, in the range of high frequencies in the order of some ten GHz.

An embodiment overcomes all or part of these disadvantages by providing a new type of switch circuit.

An embodiment provides a switch circuit comprising at least one first bipolar transistor configured to be coupled to at least one electrical component to be switched, the bipolar transistor having a first conduction electrode coupled to a reference electrical potential via at least one resistor or inductor, or a second transistor.

According to an embodiment: the bipolar transistor is of NPN type; and/or the first conduction electrode of said at least one bipolar transistor corresponds to the emitter of the bipolar transistor; and/or the switch circuit further comprises a first electrical resistor having a first terminal coupled to a base of the bipolar transistor and having a second terminal configured to be coupled to a rail of application of a first control signal; and/or the resistor or inductor corresponds to a second electrical resistor or an inductor, and comprises a first terminal coupled to the first conduction electrode of the bipolar transistor and a second terminal coupled to said reference electrical potential; and/or the first conduction electrode of the bipolar transistor is coupled to a first conduction electrode of the second transistor, and a second conduction electrode of the second transistor, for example, of NMOS or PMOS type, is coupled to the reference electrical potential.

According to an embodiment, the switch circuit further comprises a third electrical resistor having a first terminal coupled to a control electrode of the second transistor and a second terminal coupled to a rail of application of a second control signal.

According to an embodiment, the first and second control signals correspond to a same control signal or to two simultaneous signals.

According to an embodiment: said first electrode of said at least one bipolar transistor is configured to be coupled to said electrical component to be switched; and/or a second electrode of said at least one bipolar transistor is configured to be coupled to another electrical component to be switched.

According to an embodiment, said reference electrical potential is ground.

An embodiment provides a component of controllable value, comprising: a first switch circuit such as described hereabove; and a first electrical component to be switched, coupled to the first or to a second electrode of said at least one bipolar transistor of said first switch circuit; said first electrical component to be switched corresponding to an electrical capacitor or an electrical resistor or an inductor or a transistor.

According to an embodiment, the component of controllable value comprises a second electrical component to be switched, coupled to the second electrode of said at least one bipolar transistor of said first switch circuit; said first electrical component to be switched being coupled to the first electrode of said at least one bipolar transistor of said first switch circuit; said second electrical component to be switched corresponding to an electrical capacitor or an electrical resistor or an inductor or a transistor.

An embodiment provides a switch comprising: a first switch circuit such as described hereabove; and a first electrical component to be switched, coupled to the second electrode of said at least one bipolar transistor of said first switch circuit; said first electrical component to be switched corresponding to a first inductor in series with a second inductor.

According to an embodiment of the switch, a capacitor couples a junction point of the first and second inductors to ground.

According to an embodiment of the switch, the second electrode of said at least one bipolar transistor and a first terminal of the first inductor, different from a second terminal of the first inductor coupled to the junction point of the first and second inductors, are configured to be coupled to a first node of reception or of application of a differential signal.

According to an embodiment, the switch comprises a second bipolar transistor having: an emitter coupled to the first electrode of said at least one bipolar transistor of said first switch circuit; and a collector coupled to a terminal of the second inductor, different from another terminal coupled to the junction point, and to a second node of application or of reception of said differential signal.

According to an embodiment of the switch, a fourth resistor couples the base of said second bipolar transistor and the rail of application of the first control signal.

An embodiment provides a multiplexer, comprising: a plurality of switches such as described hereabove; a plurality of groups of inductors in series between two output nodes of the multiplexer; each group of inductors being arranged so that an electromagnetic coupling can be created respectively between the first inductor of one of said switches and an inductor in the group, as well as between the second inductor of said switch and another inductor in said group.

According to an embodiment, the multiplexer comprises: at least one first switch such as described hereabove; at least one second switch such as described hereabove; third, fourth, fifth, and sixth inductors in series between the output nodes of the multiplexer; the third and fourth inductors being arranged so that an electromagnetic coupling can be respectively created between the first inductor of the first switch and the third inductor, as well as between the second inductor of the first switch and the fourth inductor; the fifth and sixth inductors being arranged so that an electromagnetic coupling can be created between the first inductor of the second switch and the fifth inductor, and between the second inductor of the second switch and the sixth inductor.

An embodiment provides a method of controlling a component of controllable value such as described hereabove, comprising a change in a value of the component of variable value by the switching of said at least one bipolar transistor of said first switch circuit.

An embodiment provides a method of controlling a switch such as described hereabove, comprising the short-circuiting of the first and second inductors by the switching of said at least one bipolar transistor of said first switch circuit.

An embodiment provides a method of controlling a multiplexer such as described hereabove, comprising the selection of a signal to be transmitted the state change of a respective signal for controlling at least one of said switches.

An embodiment provides an electrical circuit comprising at least one bipolar transistor having a first conduction electrode coupled to at least one first electrical component to be switched, and also to a reference electrical potential via at least one resistor or inductor, or a field-effect transistor.

According to an embodiment, the bipolar transistor is of npn type.

According to an embodiment, the first conduction electrode corresponds to the emitter of the bipolar transistor.

According to an embodiment, the electrical circuit further comprises a first electrical resistor having a first terminal coupled to a base of the bipolar transistor and having a second terminal configured to receive a first signal for controlling the switching of the switch circuit.

According to an embodiment, the resistor or inductor corresponds to a second electrical resistor or an inductor, and comprises a first terminal coupled to the first conduction electrode of the bipolar transistor and a second terminal coupled to the reference electrical potential.

According to an embodiment, the first conduction electrode of the bipolar transistor is coupled to a first conduction electrode of the field-effect transistor, and a second conduction electrode of the field-effect transistor is coupled to the reference electrical potential.

According to an embodiment, the field-effect transistor is of type N.

According to an embodiment, the electrical circuit further comprises a third electrical resistor having a first terminal coupled to a gate of the field-effect transistor and having a second terminal configured to receive a second signal for switching the switch circuit.

According to an embodiment, the first and second signals for switching the switch circuit correspond to a same signal for switching the switch circuit.

According to an embodiment, the first electrical component to be switched corresponds to an electrical capacitor or an electrical resistor or an inductor or a transistor.

According to an embodiment, the electrical circuit further comprises a second electrical component to be switched coupled to a second conduction electrode of the bipolar transistor.

An embodiment provides a method of switching at least one electrical component to be switched, implemented based on at least one electrical circuit such as described hereabove.

An embodiment provides a device, a method, or a system comprising any feature described or shown, taken alone or in combination with another.

### BRIEF DESCRIPTION OF THE DRAWINGS

These features and advantages, as well as others, will be described in detail in the following description of specific embodiments, which is provided by way of example and is not intended to be limiting, in connection with the accompanying drawings, in which:

FIGS. 1A, 1B, and 1C schematically show examples of variable capacitors;

FIGS. 2A and 2B show examples of circuits of FIG. 1A according to embodiments;

FIGS. 3A and 3B show examples of circuits of FIG. 1A according to embodiments;

FIGS. 4A and 4B show graphs of capacitance variations as a function of frequency;

FIG. 5 shows an example of a multiplexer according to an embodiment;

FIG. 6A shows an example of a switch circuit of a multiplexer according to an embodiment;

FIGS. 6B and 6C show operating modes of the example of FIG. 6A;

FIGS. 7 and 8 show examples of switch circuits of a multiplexer according to embodiments; and

FIG. 9 shows an example of a multiplexer according to an embodiment.

### DETAILED DESCRIPTION OF ILLUSTRATIVE EMBODIMENTS

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and have been described in detail.

Unless otherwise specified, when reference is made to two elements being connected to each other, this means directly connected without any intermediate elements other than conductors, and when reference is made to two elements being coupled to each other, this means that these two elements may be connected or may be connected via one or more other elements. As used herein, including in the claims, the terms ‘and/or’ and ‘or’ are generally inclusive and encompass any combination of the listed alternatives, unless the context clearly indicates otherwise.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings, in a normal position of use.

In all the described embodiments, for each field-effect transistor, the first and second conduction electrodes correspond to two electrodes different from each other of a same transistor, one of them corresponding to the source electrode and the other corresponding to the drain electrode. Similarly, for each bipolar transistor, the first and second conduction electrodes correspond to two electrodes different from each other of a same transistor, one of them corresponding to the emitter and the other corresponding to the collector.

Unless specified otherwise, the expressions “about”, “approximately”, “substantially”, and “in the order of” signify plus or minus 10%, preferably of plus or minus 5%.

The present disclosure applies in particular to the field of radio frequency (RF) or high frequency switching, for example, in the GHz range, and also to the field of telecommunications and to the following fields: millimeter waves (MMW), 4G, 5G, 6G, Ku (“Kurz-unten”) band, Ka (“Kurz-above”) band, low Earth orbit (LEO) satellite communications, high data rate communications, D band, and bands beyond the D band.

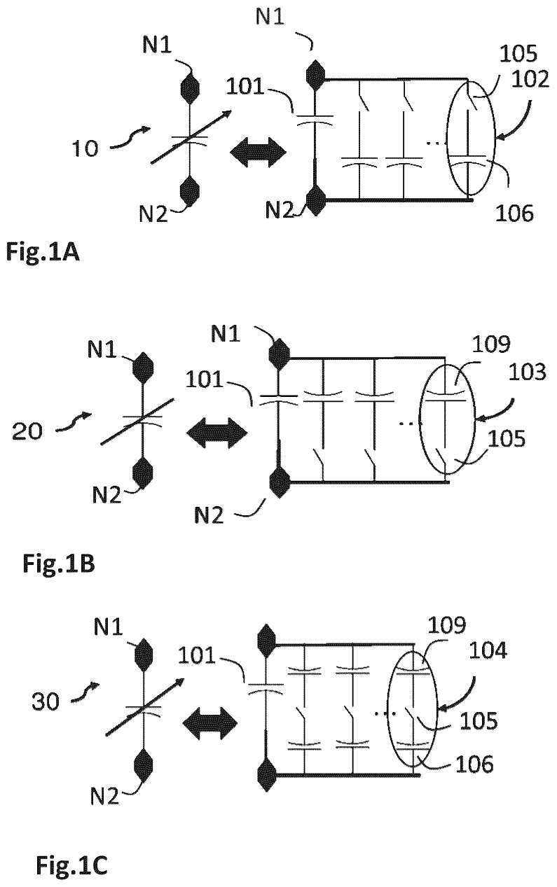

FIGS. 1A to 5 are relative to a first aspect which bears on switch circuits and their implementation, for example, in circuits of configurable value or in multiplexers.

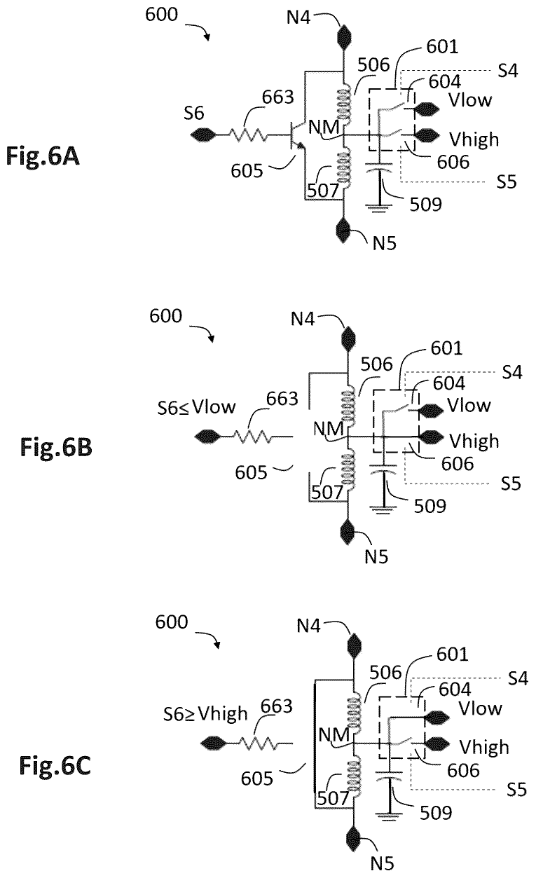

FIGS. 6 to 9 are relative to a second aspect bearing on switches and their implementation within multiplexers.

FIGS. 1A, 1B, and 1C schematically show examples of variable capacitors to which the embodiments may be applied.

More specifically, FIG. 1A schematically shows, on the left-hand side, a variable capacitor 10 between two terminals N1 and N2, and on the right-hand side, an example of implementation of this variable capacitor 10. FIG. 1B schematically shows, on the left-hand side, a variable capacitor 20 between the two terminals N1 and N2, and on the right-hand side, an example of implementation of this variable capacitor 20. FIG. 1C schematically shows, on the left-hand side, a variable capacitor 30 between the two terminals N1 and N2, and on the right-hand side, an example of implementation of this variable capacitor 30.

In the example of FIG. 1A, variable capacitor 10 is formed by a capacitor 101 coupling terminals N1 and N2, as well as by a plurality of similar or identical branches 102, coupled in parallel, and each coupling terminals N1 and N2. Each of branches 102 comprises a switch 105 in series with a capacitor 106. A terminal of switch 105 is coupled, preferably connected, to terminal N1, and an electrode of capacitor 106 is coupled, preferably connected, to terminal N2. In an example, not shown in FIG. 1A, capacitor 101 is coupled to node N1 via a switch.

In the example of FIG. 1B, variable capacitor 20 is formed by the capacitor 101 coupling terminals N1 and N2, as well as by a plurality of similar or identical branches 103, coupled in parallel, each coupling terminals N1 and N2. Each of branches 103 comprises switch 105 in series with a capacitor 109. A terminal of switch 105 is this time coupled, preferably connected, to terminal N2, and an electrode of capacitor 109 is coupled, preferably connected, to terminal N1. In an example, not shown in FIG. 1B, capacitor 101 is coupled to node N2 via a switch.

In the example of FIG. 1C, variable capacitor 30 is formed by the capacitor 101 coupling terminals N1 and N2, as well as by a plurality of similar or identical branches 104, coupled in parallel, each coupling terminals N1 and N2. Each of branches 104 comprises capacitor 109 in series with switch 105, and capacitor 106. An electrode of capacitor 109 is coupled, preferably connected, to terminal N1, and another electrode of capacitor 109 is coupled, preferably connected, to a terminal of switch 105. An electrode of capacitor 106 is coupled, preferably connected, to terminal N2, and another electrode of capacitor 106 is coupled, preferably connected, to another terminal of switch 105. In an example, not shown in FIG. 1C, capacitor 101 is replaced by a branch similar to one of branches 104.

In the examples of FIGS. 1A, 1B, and 1C, switches 105 have, for example, a behavior of resistor type. In a conductive or on conduction mode, the resistance is close to zero, while in a non-conductive or off conduction mode, the resistance is high, for example above several hundred ohms.

The examples in FIGS. 1A, 1B, and 1C show examples of variable or configurable capacitors, but it is also possible to obtain other types of components of variable value, such as for example, variable resistors or inductors, by replacing capacitors 106 or 109 with resistors or inductors.

It is further possible to obtain different types of components of variable value by using branches such as branches 102, 103, 104 in series, or by increasing the number of components or switches per branch.

By the terms “variable value”, there is equivalently meant “configurable value” or “variable physical characteristic” or “configurable physical characteristic”.

In order to obtain different types of components of variable value, it is also possible to consider having a plurality of components, similar or not, in series, for example, a plurality of resistors or inductors in series, or a plurality of switches in series, or a resistor and a switch in series, or an inductor and a switch in series, and to have connections at the junction point of these components or switches in series.

The switches 105 of the examples of FIGS. 1A, 1B, and 1C have been implemented for many years by means of field-effect transistors, such as NMOS or PMOS transistors. However, for a MOS-type transistor to have the lowest possible on-state resistance, it is necessary for its size to be fairly large. This leads to an increase in its parasitic capacitance, which in turn negatively impacts the frequency response but also the non-conductive mode due to the creation of short-circuits depending on frequency.

To overcome these disadvantages, the disclosed embodiments provide for each switch 105 to be replaced by a switch circuit comprising at least one bipolar transistor configured to be coupled to at least one electrical component to be switched, the bipolar transistor having a first conduction electrode coupled to a reference electrical potential via at least one resistor or inductor, or another transistor, for example, a field-effect or bipolar transistor.

In the following, the electrical component to be switched is, for example, a resistor, or a capacitor, or an inductor, or a plurality of these components arranged in series or in parallel. For the understanding, the element to be switched corresponds, in the examples in FIGS. 1A to 1C, to capacitors 106 or 109.

Hereafter, the terms “element to be switched” mean that said element may be coupled, or disconnected, by the action of the bipolar transistor, to or from another part of the circuit.

The use of bipolar transistors has an additional advantage over MOS or CMOS transistors, which is that the differences in threshold voltages, due to manufacturing dispersions, between two bipolar junction transistors are much smaller as compared with the dispersion of the threshold voltages of MOS transistors.

The use of bipolar transistors allows the creation of high off-state resistance as well as a low on-state resistance, while using a smaller footprint.

Replacing a MOS or field-effect transistor with a bipolar transistor is however not direct or obvious, since bipolar transistors operate with current, unlike MOS transistors. Thus, by simply replacing a MOS transistor with a bipolar transistor, the bipolar transistor would not operate optimally, or even would not operate at all. The embodiments thus provide creating a voltage or DC path (DC connection) between an electrode of the bipolar transistor, for example, between the base and/or the emitter, and a reference voltage such as ground, for example. This voltage or DC path is created by coupling a conduction electrode of the bipolar transistor to a reference electrical potential, such as for example ground, via at least one resistive component, such as a resistor, or an inductive component, such as an inductor, or a transistor, for example a field-effect transistor or another bipolar transistor.

In the conductive or on conduction mode, the current flows through the electrode, for example the emitter, of the bipolar transistor coupled to the reference potential in the direction of this reference potential. The created base-emitter voltage thus enables to turn on the transistor and the transistor resistance is low. The resistance of the resistive component is designed to be sufficiently high so as not to be predominantly used in the on state of the bipolar transistor.

In the non-conductive or off mode, the bipolar transistor is off and has an equivalent impedance, and since the resistance of the resistive element is high, the impedance at the connection with the component to be switched is high. This enables the capacitance associated with the bipolar transistor not to be seen in the off mode.

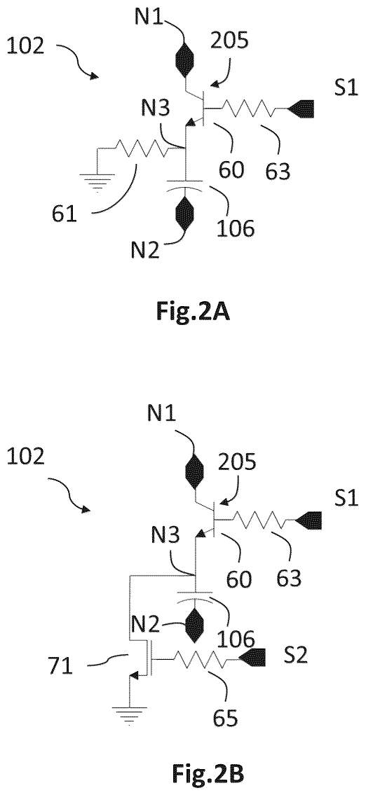

FIGS. 2A and 2B show examples of circuits of FIG. 1A according to embodiments. More particularly, the shown examples illustrate embodiments of branches 102 where switch 105 is replaced by a switch circuit 205.

In the shown example, switch circuit 205 comprises a bipolar transistor 60 having its collector coupled, preferably connected, to terminal N1, and having its emitter N3 coupled to ground via a resistor 61. Capacitor 106 couples the emitter N3 of the bipolar transistor to terminal N2. An optional resistor 63 couples the base of bipolar transistor 60 to a rail of application of a control signal S1.

Resistor 61 has a value that can be selected by those skilled in the art between a few ohms and several hundred ohms.

Resistor 63 has a value that can be selected by those skilled in the art between a few ohms and several hundred ohms.

In the example of FIG. 2A, the continuous path is obtained by the connection of the emitter to resistor 61 and its connection to ground.

The example of FIG. 2B is similar to that of FIG. 2A except that resistor 61 is replaced by a transistor 71, having a conduction node or electrode coupled, preferably connected, to the emitter of bipolar transistor 60, and another conduction node coupled, preferably connected, to ground. An optional resistor 65 couples a control node, or electrode, of transistor 71 to a rail of application of a control signal S2. Control signals S1 and S2 are, for example, the same or they may be different, or they may be two simultaneous signals.

Transistor 71 is, for example, a field-effect transistor, such as an NMOS or PMOS transistor, or a bipolar transistor.

In an on conduction mode of switch circuit 205, bipolar transistor 60 is controlled by signal S1 to be conductive, and transistor 71 is also controlled by signal S2 to be in a conductive state, which enables to obtain an equivalent resistance coupling the emitter of the bipolar transistor and ground.

In an off conduction mode of switch circuit 205, bipolar transistor 60 is controlled by signal S1 to be non-conductive, and transistor 71 is also controlled by signal S2 to be non-conductive. Transistor 71 then has a high resistance.

The example of FIG. 2B enables to have an on-state resistance which is lower than the resistance 61 of the example of FIG. 2A and an off-state resistance which is higher than the resistance 61 of the example in FIG. 2A. This enables to ensures a higher quality factor and to ensure fewer losses.

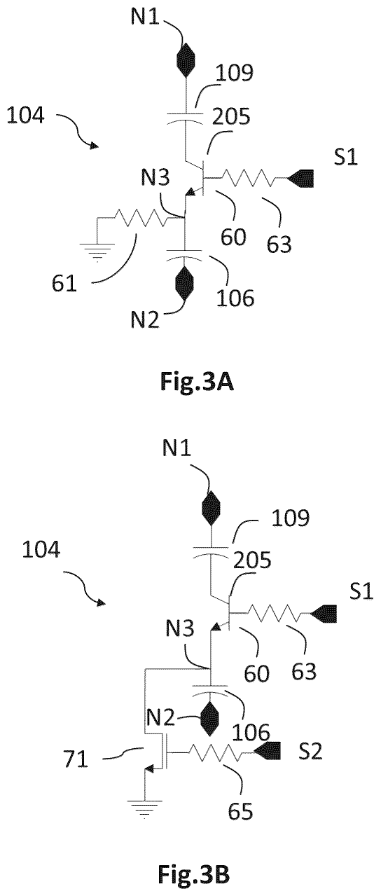

FIGS. 3A and 3B show examples of circuits of FIG. 1A according to embodiments. More particularly, the shown examples illustrate embodiments of branches 104 where switch 105 is replaced by a switch circuit 205.

The examples of FIGS. 3A and 3B are similar, respectively, to the examples of FIGS. 2A and 2B, except that capacitor 109 couples the collector of bipolar transistor 60 to terminal N1.

Although FIGS. 2A, 2B, 3A, and 3B illustrate examples of a configurable capacitor, those skilled in the art may implement one or more inductors in place of resistor 61 or transistor 71.

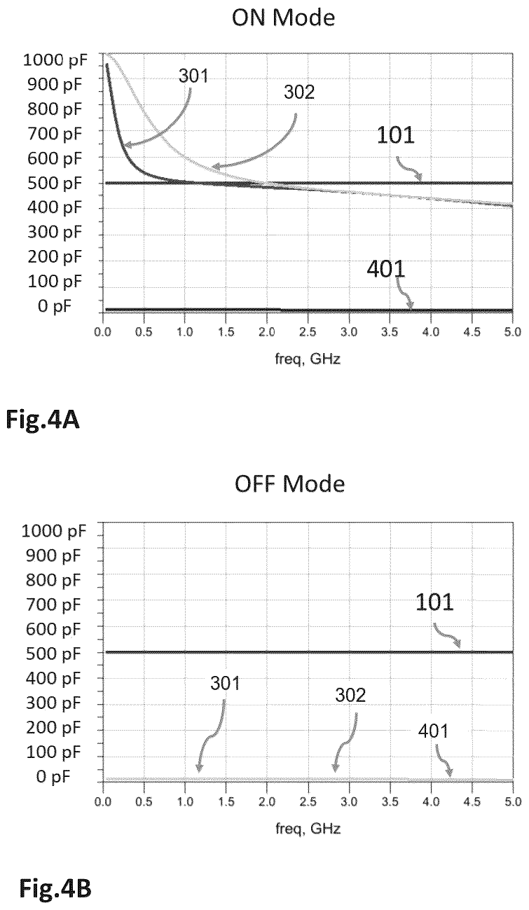

FIGS. 4A and 4B show graphs of capacitance variations as a function of frequency, respectively in a conductive mode (ON Mode) and in a non-conductive mode (OFF Mode) of switch circuit 205. More precisely, FIG. 4A shows the respective capacitors 301, 302 of the circuit of FIG. 3A and of the circuit of FIG. 3B as a function of frequency, as well as the frequency behavior of capacitor 101 alone, and finally the frequency behavior of the equivalent capacitance 401 of the circuit of FIG. 3A or 3B, but where resistor 61 or transistor 71 are absent to couple the emitter of the bipolar transistor of circuit 205 to ground. As an example, the capacitances used to obtain these graphs are 1 pF for capacitors 106 and 109, resistance 61 is 1 kOhm, and resistance 63 is 1 kOhm.

In the graph of FIG. 4A, capacitance 301 decreases rapidly between 1,000 pF and the value of capacitance 101, that is, 500 pF, between 0.1 GHz and 1 GHz. Beyond 1 GHz, capacitance 301 decreases slightly and linearly to a value of 400 pF at 5 GHz.

In the graph in FIG. 4A, capacitance 302 decreases rapidly between 1,000 pF and the value of capacitance 101 between 0.1 GHz and 2 GHz. This decrease is however less rapid than for capacitance 301. Beyond 2 GHz, capacitance 302 behaves like capacitance 301 and decreases slightly and linearly to a value of 400 pF at 5 GHz.

In the example of FIG. 4A, capacitance 101 remains stable between 0.1 and 5 GHz with a 500-pF value.

In this example, equivalent capacitance 401 remains at zero regardless of the frequency, which shows that without the addition of a continuous path between the emitter of the bipolar transistor of switch circuit 205 and ground, then the bipolar transistor alone does not operate.

There results from the example of FIG. 4B that, in the non-conductive mode (OFF mode), capacitances 301 and 302 remain very low or even zero, which enables to improve the high-frequency performance. Capacitance 401 remains equivalent to that of the example of graph 4A, which shows that the bipolar alone cannot operate to replace a MOS transistor, for example. Capacitance 101 remains stable.

It is thus demonstrated that it is possible to obtain a component of configurable value, and capable of operating at high frequencies in the order of several GHz, by using switch circuits based on bipolar transistors, creating a continuous current or voltage path between, for example, the emitter and ground, that is, between the base and the emitter (base-emitter voltage>0 V).

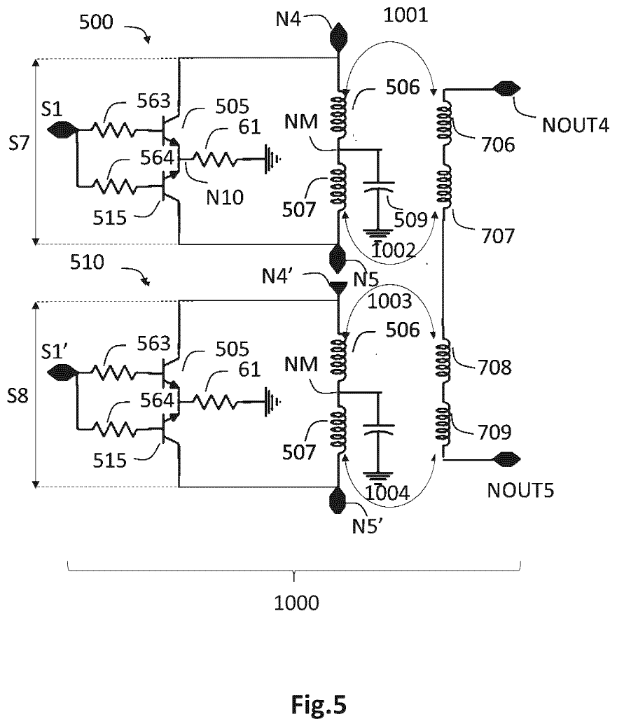

FIG. 5 shows an example of a multiplexer 1000, for example a radio frequency multiplexer, according to an embodiment.

Multiplexers enable to select, according to one or more control signals, a path or a signal to be transmitted at the output from among a plurality of incoming paths or signals.

The multiplexer 1000 of FIG. 5 comprises a first and a second switches 500, 510, which are similar or identical.

In the shown example, the first switch 500 comprises a bipolar transistor 505 coupling a node N4 of application or of reception of a differential signal S7 and a node N10. A resistive element, here illustrated by a resistor, for example similar or identical to resistor 61, couples node N10 to ground. In the shown example, the emitter of transistor 505 is coupled, preferably connected, to node N10 so as to create a voltage or DC path as seen in FIGS. 2A, 2B, 3A, and 3B. The first switch 500 further comprises an electrical resistor 563 having a first terminal coupled to a base of the bipolar transistor 505 and having a second terminal configured to be coupled to a rail of application of a control signal, for example similar to signal S1.

The first switch 500 further optionally comprises another bipolar transistor 515 coupling node N10 to another node N5 of application or of reception of differential signal S7. In the shown example, the emitter of transistor 515 is coupled, preferably connected, to node N10. An electrical resistor 564, for example similar to resistor 563, comprises a first terminal coupled to a base of bipolar transistor 515 and a second terminal coupled to the node of application of control signal S1.

Resistive element 61 enables to obtain a base-emitter voltage Vbe: low in transistors 505 and 515 when signal S1 is low to enable to turn off these transistors 505 and 515, and; high when signal S1 is in the high state, to enable to turn on transistors 505 and 515.

In the shown example, the first switch 500 further comprises two inductors 506 and 507 in series between node N4 and node N5. An optional decoupling capacitor 509 couples a junction point NM of inductors 506, 507 to ground. Inductors 506 and 507 can be viewed as being two parts of a same inductor.

The fact of having two bipolar transistors 505 and 515 arranged as shown in the example of FIG. 5 enables to short-circuit the two inductors 506 and 507 in similar fashion when bipolar transistors 505 and 515 are conductive.

The second switch 510 is, for example, similar or identical to switch 500 except that instead of control signal S1, it receives another signal S1′ which may, for example, be opposite or complementary to signal S1. The second switch 510 is applied or receives a differential signal S8, for example different from signal S7, between nodes N4′ and N5′ which correspond to the nodes N4 and N5 of the first switch 500 but applied to the second switch 510.

In a transmit mode, signals S7 and S8 correspond, for example, to signals respectively applied to the nodes N4, N5, and N5, N5′ to be selected, and so that one of them ends up at the multiplexer output. In a transmit or emit mode, a signal arriving at the output of the multiplexer may be distributed to one or the other of switches 500, 510, at nodes N4, N5 or N4′, N5′ depending on the selection performed.

In the illustrated example, multiplexer 1000 further comprises four inductors in series 706, 707, 708, 709 between output nodes NOUT4 and NOUT5. Inductors 706 and 707 are arranged, for example, so that an electromagnetic coupling 1001 can be created between the inductor 506 of the first switch 500 and inductor 706, and that an electromagnetic coupling 1002 can be created between the inductor 507 of the first switch 500 and inductor 707. Inductors 708, 709 are arranged so that an electromagnetic coupling 1003 can be created between the inductor 506 of the second switch 510 and inductor 708, and that an electromagnetic coupling 1004 can be created between the second inductor 507 of the second switch 510 and inductor 709.

Switches 500, 510 form different channels which are selectable, both in transmission and reception, by the state of signals S1 and S1′.

The inductors 506, 507 of each of switches 500, 510 form the primary stage of a transformer of BALUN (balanced/unbalanced) type. Inductors 706, 707 and 708, 709 form the secondary stage of this transformer.

Depending on the state of signals S1 and S1′, switches 500 and 510 are on or off. For example, when signal S1 is in the high state and signal S1′ is in the low state, the inductors 506 and 507 of the first switch 500 are short-circuited because bipolar transistors 505 and 515 are on, which implies that inductors 506 and 507 are then short-circuited and thus equivalent to an inductor having a very low value. Since couplings 1001 and 1002 couple inductors 506 to 706 and 507 to 707, then, effectively, inductors 706 and 707 become very low. The upper part of this example of a multiplexer is equivalent to a short-circuit. Conversely, the bipolar transistors 505 and 515 of the second switch 510 are then non-conductive, which means that differential signal S8 can propagate via electromagnetic couplings 1003 and 1004 to output nodes NOUT4 and NOUT5. Conversely, when signal S1 is in the low state and signal S1′ is in the high state, the inductors 506 and 507 of the second switch 510 are short-circuited, which implies that inductors 506 and 507 are then short-circuited and thus equivalent to an inductor of very low value. Since couplings 1003 and 1004 couple inductors 506 to 708 and 507 to 709, then inductors 708 and 709 effectively become very low. The lower part of this example of a multiplexer is equivalent to a short-circuit. On the contrary, the bipolar transistors 505 and 515 of the first switch 500 are then non-conductive, which means that differential signal S7 can propagate, via electromagnetic couplings 1001 and 1002, on output nodes NOUT4 and NOUT5.

The example of FIG. 5 thus enables to form a multiplexer based on bipolar transistors where, depending on the state of signals S1 and S1′, and in transmit mode, one of signals S7 or S8 is selected to be present on output nodes NOUT4 and NOUT5.

In other words, the multiplexer 1000 of FIG. 5 enables, in transmit mode (TX), to select a signal from among the differential signals S7 and S8 applied to nodes N4, N5, N4′, and N5′, respectively, so that the selected signal is output between nodes NOUT4 and NOUT5 of the multiplexer.

Conversely, in a receive mode (RX), multiplexer 1000 enables to select the channel, that is, the nodes N4, N5, or N4′, N5′, to which an incoming signal present on nodes NOUT4 and NOUT5 will be directed.

A second aspect concerns switches based on bipolar transistors and multiplexers implemented by means of these multiplexers.

FIG. 6A shows an example of a switch 600, also called switch circuit, for example for multiplexers, according to an embodiment.

In the example of FIG. 6A, switch 600 comprises a bipolar transistor 605, having: its collector coupled, preferably connected, to a node N4 of application or of reception of a signal, for example, differential, and for example similar to the node N4 of FIG. 5; and its emitter coupled, preferably connected, to a node N5 of application or of reception of a signal, for example, differential, and for example similar or identical to the node N5 of FIG. 5.

The base of bipolar transistor 605 is coupled to a rail of application of a control signal S6 via a resistor 663.

In the illustrated example, switch 600 comprises two inductors in series 506, 507, for example similar to the inductors 506, 507 of FIG. 5, between node N4 and node N5. An optional decoupling capacitor 509, for example similar or identical to the capacitor 509 of FIG. 5, couples the junction point NM of inductors 506, 507 to ground.

In the example of FIG. 6A, switch 600 further comprises a selection circuit 601, configured to controllably couple the junction point NM of the inductors either to a rail of application of a voltage Vlow via a switch 604 or to a rail of application of a voltage Vhigh via a switch 606. In an example, voltage Vlow is lower than Vhigh. For example, voltage Vlow is equal to or lower than o V, and voltage Vhigh is greater than or equal to a trigger threshold voltage, typically above 0.6 V, up to several volts. Switches 604 and 606 have their on conduction mode respectively controlled by the state of a signal S4 and of a signal S5.

In an example, switches 604 and 606 are transistors, for example of MOS or bipolar type.

FIGS. 6B and 6C show operating modes of the example of FIG. 6A.

In the example of FIG. 6B, signal S5 turns on switch 606, signal S4 leaves switch 604 off, voltage Vhigh is thus present at the junction point of inductors 506 and 507, and is then present at nodes N4 and N5. When a voltage of signal S6 is equal to, similar to, or lower than voltage Vlow, and voltage Vhigh is present, by the action of switch 606, at nodes N4 and N5, then bipolar transistor 605 becomes non-conductive or off because voltage Vbe is not positive or then zero, and thus no current path is created.

In FIG. 6C, signal S4 turns on switch 604, and signal S5 leaves switch 606 off, voltage Vlow is then present at the junction point of inductors 506 and 507, and is then present at nodes N4 and N5. When the voltage of signal S6 is equal to, similar to, or greater than voltage Vhigh, and voltage Vlow is present, by the action of switch 604, at nodes N4 and N5, then bipolar transistor 605 becomes conductive and inductors 506 and 507 are thus short-circuited.

Selection circuit 601 thus enables, according to control signal S6, to define the conduction state of bipolar transistor 605.

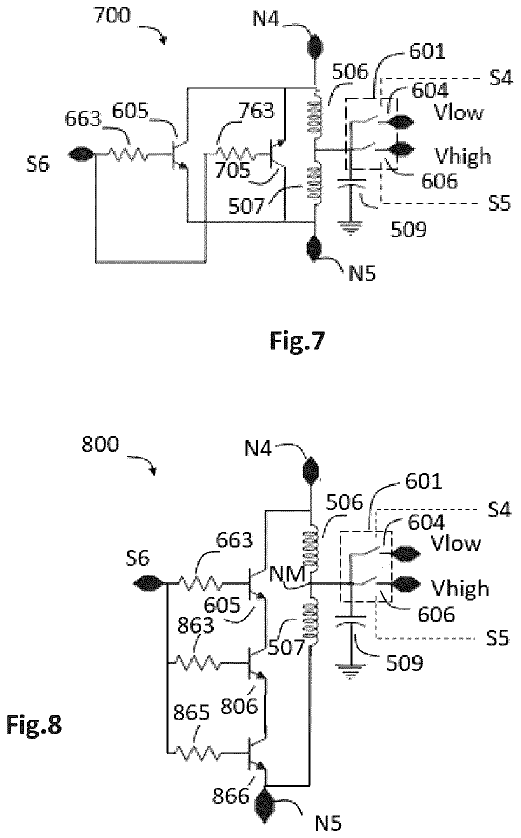

FIGS. 7 and 8 show examples of switch 700, for example for multiplexers, according to embodiments.

Switch 700 is similar to the switch 600 of FIG. 6A except that it comprises an additional bipolar transistor 705 coupling node N4 and node N5. The collector of transistor 705 is coupled, preferably connected, to node N5, and the emitter of transistor 705 is coupled, preferably connected, to node N4. A resistor 763 couples the base of transistor 705 to the rail of application of signal S6.

Switch 800 is similar to switch 600 of FIG. 6A except that it comprises a plurality of, for example two, additional bipolar transistors 806, 866 in series with transistor 605. The collector of bipolar transistor 806 is coupled, preferably connected, to the emitter of bipolar transistor 605, and its emitter is coupled, preferably connected, to the collector of transistor 866. The emitter of transistor 866 is coupled, preferably connected, to node N5. A resistor 863 couples the base of transistor 806 to the rail of application of signal S6. A resistor 865 couples the base of transistor 866 to the rail of application of signal S6.

The example of FIG. 7 enables to improve symmetry through the use of two mirrored transistors 605 and 705.

The example of FIG. 8 enables to withstand a higher voltage amplitude due to the use of a plurality of bipolar transistors in parallel.

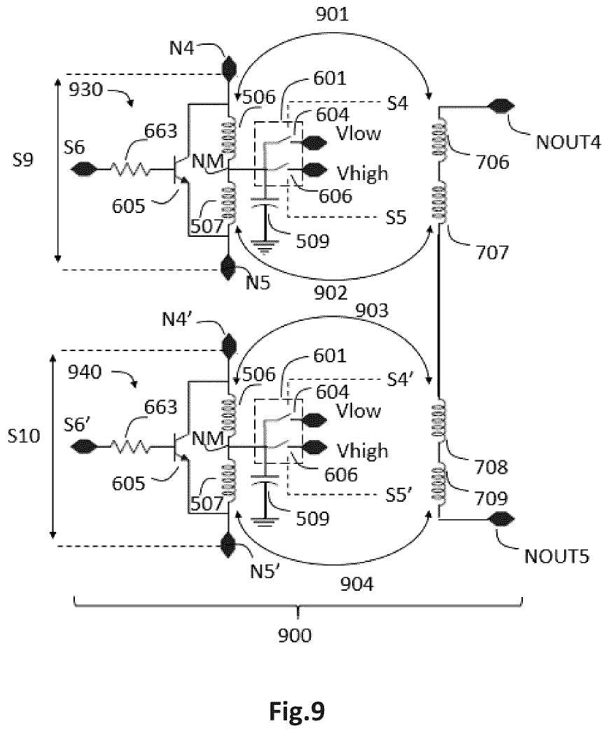

FIG. 9 shows an example of a multiplexer 900 according to an embodiment.

The multiplexer 900 of FIG. 9 enables to select a signal from among differential signals S9 and S10, so that in a transmit mode, the selected signal is output between nodes NOUT4 and NOUT5 of the multiplexer.

The multiplexer 900 of FIG. 9 comprises two switches 930, 940 which are similar or identical to the switch 600 of FIG. 6A.

Switch 930 receives a control signal, in other words a switching signal S6, for example similar to the signal S6 of FIG. 6A. Switch 930 is configured so that differential signal S9 is applied between nodes N4 and N5 in transmit mode, or so that it is received between these nodes N4 and N5 in receive mode.

Switch 940 is, for example, similar or identical to switch 930 except that instead of control signal S6, it receives another control signal which may be, for example, opposite or complementary to signal S6, and which receives differential signal S10, for example different from signal S9, between nodes N4′ and N5′. Nodes N4′ and N5′ correspond to the nodes N4 and N5 of the switch 600 of FIG. 6A but applied to switch 940.

In the shown example, multiplexer 900 further comprises four inductors in series 706, 707, 708, 709, between the output nodes NOUT4 and NOUT5. Inductors 706, 707 are, for example, arranged so that an electromagnetic coupling 901 can be created between the inductor 506 of switch 930 and inductor 706, and so that an electromagnetic coupling 902 can be created between the inductor 507 of switch 930 and inductor 707. Inductors 708, 709 are arranged so that an electromagnetic coupling 903 can be created between the inductor 506 of switch 940 and inductor 708, and so that an electromagnetic coupling 904 can be created between the second inductor 507 of switch 940 and inductor 709.

The inductors 506, 507 of each of switches 500, 510 form the primary stage of a BALUN-type transformer. Inductors 706, 707 and 708, 709 form the secondary stage of these transformers.

Depending on the state of signals S6 and S6′, and on the state of switches 604 and 606, the respective transistors 605 of each of switches 930 and 940 are on or off. For example, when signal S6 is in the high state, that is, equal to or greater than Vhigh, while the switch 604 of switch 930 is on, and signal S6′ is in the low state, that is, equal to or lower than Vlow, while the switch 606 of switch 940 is on, the inductors 506 and 507 of switch 930 are short-circuited and the inductors 506 and 507 of switch 940 are not short-circuited. This implies that inductors 706 and 707 are also short-circuited with the coupling 901 and 902 to inductors 506 and 507. Differential signal S10 can then propagate via electromagnetic couplings 903 and 904, to output nodes NOUT4 and NOUT5.

Conversely, when signal S6 is in the low state while the switch 606 of switch 930 is on, and signal S6′ is in the high state while the switch 604 of switch 940 is on, then the inductors 506 and 507 of switch 940 are short-circuited. Inductors 708 and 709 are also short-circuited with the coupling 903 and 904 to inductors 506 and 507. Differential signal S9 can then propagate, via electromagnetic couplings 901 and 902, to output nodes NOUT4 and NOUT5.

The example in FIG. 9 thus enables to form a multiplexer based on bipolar transistors where, depending on the state of signals S6 and S6′ and depending on the state of the switches 604, 606 of each of the switches, in a transmit mode, one of signals S9 or S10 is selected to be present on output nodes NOUT4 and NOUT5, and in a receive mode, one of switches 930, 940 is selected to receive on these nodes N4, N5 or N4′, N5′ the signal present on nodes NOUT4, NOUT5.

In other words, the multiplexer 900 of FIG. 9 enables, in transmit mode (TX), to select a signal from among the differential signals S9 and S10 applied to the respective nodes N4, N5, N4′, N5′, so that the selected signal is output between the nodes NOUT4 and NOUT5 of the multiplexer.

Conversely, in a receive mode (RX), multiplexer 900 enables to select the channel towards which, that is, the nodes N4, N5, or N4′, N5′ towards which, a signal present on nodes NOUT4 and NOUT5 will be directed.

The example of FIG. 9 enables, in receive mode, to obtain for example low insertion losses in the order of 2.5 dB for frequencies between 12 and 14.25 GHz, while the impedance is high, for example around 100.2 Ohms, on the transmit side and low, for example around 2.6 Ohms, on the receive side.

The example of FIG. 9 enables, in transmit mode, to obtain low insertion losses in the order of 2.5 dB for frequencies between 12 and 14.25 GHz, while the impedance is high, for example around 100.6 Ohms, on the transmit side and low, for example around 2.6 Ohms, on the receive side.

All of the above examples have been described with switches used to couple capacitors together. As a variant, these examples may apply to couple, in alternation or in combination, inductors, capacitors, electrical resistors, transistors, or other types of components.

In the various described examples, the bipolar transistors are of NPN type. As a variant, the bipolar transistors may be of PNP type.

In the various described examples, the field-effect transistors are of type N. As a variant, the field-effect transistors may be of type P.

The various examples of embodiment enable to form RF switches less expensive than those based on MOS technologies.

In the various examples of embodiment, the switches can be made in bipolar technology.

In the various examples of embodiment, a small surface area controlled by a small bipolar surface can be achieved, with no additional cost.

There is provided a circuit enabling to decrease the surface area occupied by RF components while maintaining a switching in operating frequencies such as the Ka or Ku band.

The following examples of embodiments concern the second aspect.
Example 1: Switch 600, 700, 800, 930, 940, for example radio frequency, comprising: at least one first bipolar transistor 605 coupling a first node N4 of application or of reception of a differential signal S7, S8, S9, S10 and a second node N5 of application or of reception of differential signal S7, S8, S9, S10; a first and a second inductor 506, 507 in series between the first node N4 and the second node N5; a selection circuit 601, configured to couple, in controllable manner, a junction point NM of the first and second inductors 506, 507, either to a rail of application of a first voltage Vlow or to a rail of application of a second voltage Vhigh.
Example 2: Switch 600, 700, 800, 930, 940 according to example 1, in which a capacitor 109 couples the junction point of the first and second inductors 106, 107 to ground.
Example 3: Switch 600, 700, 800, 930, 940 according to example 1 or 2, in which switch 600, 700, 800, 930, 940 further comprises a first electrical resistor 663, having a first terminal coupled to a base of the first bipolar transistor 605 and a second terminal coupled to a rail of application of a first control signal S6, S6′.
Example 4: Switch 700 according to any of examples 1 to 3, in which switch 700 comprises a second bipolar transistor 705 coupling the first node N4, N4′ and the second node N5, N5′; an emitter of the first bipolar transistor being coupled to a collector of the second bipolar transistor, and an emitter of the second bipolar transistor being coupled to a collector of the first bipolar transistor.
Example 5: Switch 700 according to examples 3 and 4, in which switch 700 further comprises a second electrical resistor 763 having a first terminal coupled to a base of the second bipolar transistor and a second terminal coupled to said rail of application of the first control signal S6.
Example 6: Switch according to any of examples 1 to 3, in which the first bipolar transistor 605 couples the first node N4, N4′ and the second node N5, N5′ via one or more third transistors 806, 866 coupled in series between the first bipolar transistor 605 and the second node N5, N5′.
Example 7: Switch according to example 6, in which the base of each of said one or more third transistors 806, 866 is coupled to a first terminal of a respective third resistor 863, 865, each of said third resistors having a second terminal coupled to said rail of application of the first control signal S6, S6′.
Example 8: Switch according to example 6 or 7, in which the emitter of at least one of said third transistors is coupled to the collector of the next third transistor in the series.
Example 9: Switch according to any of examples 1 to 8, in which selection circuit 601 comprises: a first switch 604 coupling the junction point NM of the first and second inductors 506, 507 to the rail of application of the first voltage Vlow; and/or a second switch 606 coupling the junction point NM of the first and second inductors 506, 507 to the rail of application of the second voltage Vhigh.
Example 10: Switch according to any of examples 1 to 9, in which the first voltage Vlow is lower than the second voltage Vhigh.
Example 11: Switch according to example 9 as dependent on example 3, or example 10 as dependent on example 9 and example 3, in which in order for the switch to be in a first state where the first and second inductors 506, 507 are short-circuited, a voltage of the first control signal S6 is equal to, or similar to, or higher than the second voltage Vhigh, and the first switch is controlled to be conductive.
Example 12: Switch according to example 9 as dependent on example 3, or according to example 10 or 11, wherein, for the switch to be in a second state where the first transistor 605 is non-conductive, a voltage of the first control signal S6 is equal to, or similar to, or lower than the first voltage Vlow, and the second switch 606 is controlled to be conductive.
Example 13: Multiplexer comprising: a first switch 600, 700, 800, 930, according to any of examples 1 to 12; a second switch 600, 700, 800, 940 according to any of examples 1 to 12; third, fourth, fifth, and sixth inductors in series 706, 707, 708, 709; the third and fourth inductors 706, 707 being arranged so that an electromagnetic coupling 901, 902 can be created respectively between the first inductor 506 of the first switch and the third inductor 706, as well as between the second inductor 507 of the first switch and the fourth inductor 707; the fifth and sixth inductors 708, 709 are arranged so that an electromagnetic coupling 903, 904 can be created between the first inductor 506 of the second switch and the fifth inductor 507, as well as between the second inductor 507 of the second switch and the sixth inductor 709.
Example 14: Multiplexer according to example 13, wherein: the first and second nodes N4, N5 of the first switch 600, 700, 800, 930 are configured so that a first differential signal S7, S9 is applied thereto or is received thereon; and the first and second nodes N4′, N5′ of the second switch 600, 700, 800, 940 are configured to receive a second differential signal S8, S10 different from the first differential signal S7, S9.
Example 15: Multiplexer according to examples 13 and 14 as dependent on examples 10 to 13, in which a level of the first control signal S6 of the first switch and a level of the first control signal S6′ of the second switch are opposite or complementary.

Various embodiments and variants have been described. The person skilled in the art will understand that certain features of these various embodiments and variants could be combined, and other variants will become apparent to the person skilled in the art. In particular, with regard to the multiplexers 900 and 1000 of FIGS. 9 and 5, although described for selection from among two signals, respectively S9 and S10, or S7 and S8, those skilled in the art will be capable of adapting the number of switches to the number of signals to be selected by adding one switch per additional signal to be selected and by adding at least one inductor per additional switch, each additional inductor being in series with inductors 706, 707, 708, 709 and arranged to be able to achieve an electromagnetic coupling with the inductor(s) 506, 507 of the additional switches. Further, multiplexer 900 may be implemented by using switches 700 or 800 instead of switches 930, 940.

Finally, the practical implementation of the described embodiments and variants is within the abilities of those skilled in the art based on the functional indications given hereabove. In particular, the examples in FIGS. 5 to 9 can be considered in the case of a signal which is not differential but which would only be applied to the node N4 or N4′, for example, of each switch. In this case, the second inductor 507 of the switches would, for example, be absent or would be in an asymmetrical (single-ended) configuration where its terminals opposite to that coupled, preferably connected, to node NM would be left at a floating potential. Additionally, even though the examples of FIGS. 5 and 9 illustrate a secondary stage with four inductors in series, those skilled in the art may consider only two inductors in series, as long as each of them can provide a satisfactory electromagnetic coupling with the inductors 506, 507 of the respective switch. In other words, the secondary of the multiplexer may be formed of inductors in series with a single inductor per switch present at the primary.

WHAT IS CLAIMED IS:
1. a switch circuit comprising:
at least one first bipolar transistor configured to be coupled to at least one electrical component to be switched, the bipolar transistor comprising a first emitter/collector electrode coupled to a reference electrical potential via at least one resistor or inductor, or a second transistor.
2. The switch circuit according to claim 1, wherein:
the bipolar transistor is of NPN type;
the first emitter/collector electrode of the at least one bipolar transistor corresponds to the emitter of the bipolar transistor;
the switch circuit further comprises a first electrical resistor having a first terminal coupled to a base of the bipolar transistor and a second terminal configured to be coupled to a rail of application of a first control signal;
the resistor or inductor corresponds to a second electrical resistor or an inductor, and comprises a first terminal coupled to the first emitter/collector electrode of the bipolar transistor and a second terminal coupled to the reference electrical potential; or
the emitter/collector electrode of the bipolar transistor is coupled to a first emitter/collector electrode of the second transistor, and wherein a second emitter/collector electrode of the second transistor is coupled to the reference electrical potential.
3. The switch circuit according to claim 2, further comprising a third electrical resistor having a first terminal coupled to a control electrode of the second transistor and a second terminal coupled to a rail of application of a second control signal.
4. The switch circuit according to claim 3, wherein the first and second control signals correspond to a same control signal or to two simultaneous signals.
5. The switch circuit according to claim 1, wherein:
the first emitter/collector electrode of the at least one bipolar transistor is configured to be coupled to the electrical component to be switched; or
a second emitter/collector electrode of the at least one bipolar transistor is configured to be coupled to another electrical component to be switched.
6. The switch circuit according to claim 1, wherein the reference electrical potential is ground.
7. A component of controllable value, comprising:
a first switch circuit according to claim 1; and
a first electrical component to be switched, coupled to the first emitter/collector electrode or to a second emitter/collector electrode of the at least one bipolar transistor of the first switch circuit; and
the first electrical component to be switched corresponding to an electrical capacitor, an electrical resistor, an inductor, or a transistor.
8. The component of controllable value according to claim 7, further comprising:
a second electrical component to be switched, coupled to the second emitter/collector electrode of the at least one bipolar transistor of the first switch circuit;
the first electrical switching component being coupled to the first emitter/collector electrode of the at least one bipolar transistor of the first switch circuit; and
the second electrical component to be switched corresponding to an electrical capacitor, an electrical resistor, an inductor, or a transistor.
9. a switch comprising:
a first switch circuit comprising at least one first bipolar transistor configured to be coupled to at least one electrical component to be switched, the bipolar transistor comprising a first emitter/collector electrode coupled to a reference electrical potential via at least one resistor, inductor, or a second transistor; and
a first electrical component to be switched, coupled to the second emitter/collector electrode of the at least one bipolar transistor of the first switch circuit, the first electrical component to be switched corresponding to a first inductor in series with a second inductor.
10. The switch according to claim 9, wherein a capacitor couples a junction point of the first and second inductors to ground.
11. The switch according to claim 10, wherein the second emitter/collector electrode of the at least one bipolar transistor and a first terminal of the first inductor, different from a second terminal of the first inductor coupled to the junction point of the first and second inductors, are configured to be coupled to a first node of reception or of application of a differential signal.
12. The switch according to claim 11, further comprising a second bipolar transistor comprising:
an emitter coupled to the first emitter/collector electrode of the at least one bipolar transistor of the first switch circuit; and
a collector coupled to a terminal of the second inductor, different from another terminal coupled to the junction point, and to a second node of application or of reception of the differential signal.
13. The switch according to claim 12,
wherein:
the bipolar transistor is of NPN type;
the first emitter/collector electrode of the at least one bipolar transistor corresponds to the emitter of the bipolar transistor;
the switch circuit further comprises a first electrical resistor having a first terminal coupled to a base of the bipolar transistor and a second terminal configured to be coupled to a rail of application of a first control signal;
the resistor or inductor corresponds to a second electrical resistor or an inductor, and comprises a first terminal coupled to the first emitter/collector electrode of the bipolar transistor and a second terminal coupled to the reference electrical potential; or
the first emitter/collector electrode of the bipolar transistor is coupled to a first emitter/collector electrode of the second transistor, and wherein a second emitter/collector electrode of the second transistor is coupled to the reference electrical potential; and
wherein a fourth resistor couples the base of the second bipolar transistor and the rail of application of the first control signal.
14. A multiplexer, comprising:
a plurality of switches according to claim 9;
a plurality of groups of inductors in series between two output nodes of the multiplexer; and
each group of inductors being arranged so that an electromagnetic coupling is created respectively between the first inductor of one of the switches and an inductor in the group, and between the second inductor of the switch and another inductor in the group.
15. The multiplexer according to claim 14, comprising:
at least one first switch of the plurality of switches;
at least one second switch of the plurality of switches;
third, fourth, fifth, and sixth inductors in series between the output nodes of the multiplexer;
the third and fourth inductors being arranged so that an electromagnetic coupling is created respectively between the first inductor of the first switch and the third inductor as well as between the second inductor of the first switch and the fourth inductor; and
the fifth and sixth inductors being arranged so that an electromagnetic coupling is created between the first inductor of the second switch and the fifth inductor as well as between the second inductor of the second switch and the sixth inductor.
16. A method of switching at least one electrical component, comprising:
providing a switch circuit comprising at least one first bipolar transistor configured to be coupled to the at least one electrical component to be switched, the bipolar transistor comprising a first emitter/collector electrode coupled to a reference electrical potential via at least one resistor, inductor, or a second transistor; and
switching the at least one bipolar transistor of the switch circuit.
17. The method according to claim 16, wherein:
the at least one electrical component comprises a first electrical component to be switched coupled to a first emitter/collector electrode or to a second emitter/collector electrode of the at least one bipolar transistor;
the first electrical component to be switched corresponds to an electrical capacitor, an electrical resistor, an inductor, or a transistor; and
the switching comprises changing a value of a component of controllable value by the switching of the at least one bipolar transistor.
18. The method according to claim 16, wherein:
the at least one electrical component comprises a first inductor in series with a second inductor coupled to a second electrode of the at least one bipolar transistor; and
the switching comprises short-circuiting the first and second inductors by the switching of the at least one bipolar transistor.
19. The method according to claim 18, wherein:
the switch circuit is part of a multiplexer comprising a plurality of switches, each switch comprising a respective first inductor in series with a respective second inductor;
the multiplexer further comprises a plurality of groups of inductors in series between two output nodes of the multiplexer;
each group of inductors is arranged so that an electromagnetic coupling is created respectively between the first inductor of one of the switches and an inductor in the group, and between the second inductor of the switch and another inductor in the group; and
the method further comprises selecting a signal to be transmitted by a state change of a respective control signal for controlling at least one of the switches.

What is claimed is:

1. A switch circuit comprising:
at least one first bipolar transistor configured to be coupled to at least one electrical component to be switched, the bipolar transistor comprising a first emitter/collector electrode coupled to a reference electrical potential via at least one resistor or inductor, or a second transistor.

2. The switch circuit according to claim 1, wherein:
the bipolar transistor is of NPN type;
the first emitter/collector electrode of the at least one bipolar transistor corresponds to the emitter of the bipolar transistor;
the switch circuit further comprises a first electrical resistor having a first terminal coupled to a base of the bipolar transistor and a second terminal configured to be coupled to a rail of application of a first control signal;
the resistor or inductor corresponds to a second electrical resistor or an inductor, and comprises a first terminal coupled to the first emitter/collector electrode of the bipolar transistor and a second terminal coupled to the reference electrical potential; or
the emitter/collector electrode of the bipolar transistor is coupled to a first emitter/collector electrode of the second transistor, and wherein a second emitter/collector electrode of the second transistor is coupled to the reference electrical potential.

3. The switch circuit according to claim 2, further comprising a third electrical resistor having a first terminal coupled to a control electrode of the second transistor and a second terminal coupled to a rail of application of a second control signal.

4. The switch circuit according to claim 3, wherein the first and second control signals correspond to a same control signal or to two simultaneous signals.

5. The switch circuit according to claim 1, wherein:
the first emitter/collector electrode of the at least one bipolar transistor is configured to be coupled to the electrical component to be switched; or
a second emitter/collector electrode of the at least one bipolar transistor is configured to be coupled to another electrical component to be switched.

6. The switch circuit according to claim 1, wherein the reference electrical potential is ground.

7. A component of controllable value, comprising:
a first switch circuit according to claim 1; and
a first electrical component to be switched, coupled to the first emitter/collector electrode or to a second emitter/collector electrode of the at least one bipolar transistor of the first switch circuit; and
the first electrical component to be switched corresponding to an electrical capacitor, an electrical resistor, an inductor, or a transistor.

8. The component of controllable value according to claim 7, further comprising:
a second electrical component to be switched, coupled to the second emitter/collector electrode of the at least one bipolar transistor of the first switch circuit;
the first electrical switching component being coupled to the first emitter/collector electrode of the at least one bipolar transistor of the first switch circuit; and
the second electrical component to be switched corresponding to an electrical capacitor, an electrical resistor, an inductor, or a transistor.

9. A switch comprising:
a first switch circuit comprising at least one first bipolar transistor configured to be coupled to at least one electrical component to be switched, the bipolar transistor comprising a first emitter/collector electrode coupled to a reference electrical potential via at least one resistor, inductor, or a second transistor; and
a first electrical component to be switched, coupled to the second emitter/collector electrode of the at least one bipolar transistor of the first switch circuit, the first electrical component to be switched corresponding to a first inductor in series with a second inductor.

10. The switch according to claim 9, wherein a capacitor couples a junction point of the first and second inductors to ground.

11. The switch according to claim 10, wherein the second emitter/collector electrode of the at least one bipolar transistor and a first terminal of the first inductor, different from a second terminal of the first inductor coupled to the junction point of the first and second inductors, are configured to be coupled to a first node of reception or of application of a differential signal.

12. The switch according to claim 11, further comprising a second bipolar transistor comprising:
an emitter coupled to the first emitter/collector electrode of the at least one bipolar transistor of the first switch circuit; and
a collector coupled to a terminal of the second inductor, different from another terminal coupled to the junction point, and to a second node of application or of reception of the differential signal.

13. The switch according to claim 12,
wherein:
the bipolar transistor is of NPN type;
the first emitter/collector electrode of the at least one bipolar transistor corresponds to the emitter of the bipolar transistor;
the switch circuit further comprises a first electrical resistor having a first terminal coupled to a base of the bipolar transistor and a second terminal configured to be coupled to a rail of application of a first control signal;
the resistor or inductor corresponds to a second electrical resistor or an inductor, and comprises a first terminal coupled to the first emitter/collector electrode of the bipolar transistor and a second terminal coupled to the reference electrical potential; or
the first emitter/collector electrode of the bipolar transistor is coupled to a first emitter/collector electrode of the second transistor, and wherein a second emitter/collector electrode of the second transistor is coupled to the reference electrical potential; and
wherein a fourth resistor couples the base of the second bipolar transistor and the rail of application of the first control signal.

14. A multiplexer, comprising:
a plurality of switches according to claim 9;
a plurality of groups of inductors in series between two output nodes of the multiplexer; and
each group of inductors being arranged so that an electromagnetic coupling is created respectively between the first inductor of one of the switches and an inductor in the group, and between the second inductor of the switch and another inductor in the group.

15. The multiplexer according to claim 14, comprising:
at least one first switch of the plurality of switches;
at least one second switch of the plurality of switches;
third, fourth, fifth, and sixth inductors in series between the output nodes of the multiplexer;
the third and fourth inductors being arranged so that an electromagnetic coupling is created respectively between the first inductor of the first switch and the third inductor as well as between the second inductor of the first switch and the fourth inductor; and
the fifth and sixth inductors being arranged so that an electromagnetic coupling is created between the first inductor of the second switch and the fifth inductor as well as between the second inductor of the second switch and the sixth inductor.

16. A method of switching at least one electrical component, comprising:
providing a switch circuit comprising at least one first bipolar transistor configured to be coupled to the at least one electrical component to be switched, the bipolar transistor comprising a first emitter/collector electrode coupled to a reference electrical potential via at least one resistor, inductor, or a second transistor; and
switching the at least one bipolar transistor of the switch circuit.

17. The method according to claim 16, wherein:
the at least one electrical component comprises a first electrical component to be switched coupled to a first emitter/collector electrode or to a second emitter/collector electrode of the at least one bipolar transistor;
the first electrical component to be switched corresponds to an electrical capacitor, an electrical resistor, an inductor, or a transistor; and
the switching comprises changing a value of a component of controllable value by the switching of the at least one bipolar transistor.

18. The method according to claim 16, wherein:
the at least one electrical component comprises a first inductor in series with a second inductor coupled to a second electrode of the at least one bipolar transistor; and
the switching comprises short-circuiting the first and second inductors by the switching of the at least one bipolar transistor.

19. The method according to claim 18, wherein:
the switch circuit is part of a multiplexer comprising a plurality of switches, each switch comprising a respective first inductor in series with a respective second inductor;
the multiplexer further comprises a plurality of groups of inductors in series between two output nodes of the multiplexer;
each group of inductors is arranged so that an electromagnetic coupling is created respectively between the first inductor of one of the switches and an inductor in the group, and between the second inductor of the switch and another inductor in the group; and
the method further comprises selecting a signal to be transmitted by a state change of a respective control signal for controlling at least one of the switches.
